(19) United States
(12) Patent Application Publication
(10) Pub. No.: US 2025/0102923 A1
(43) Pub. Date: Mar. 27, 2025

(54) A FRAMEWORK FOR CONDITION TUNING AND IMAGE PROCESSING FOR METROLOGY APPLICATIONS

(71) Applicant: ASML Netherlands B.V., Veldhoven (NL)

(72) Inventors: Lingling PU, San Jose, CA (US); Zijian DU, San Jose, CA (US)

(73) Assignee: ASML Netherlands B.V., Veldhoven (NL)

(21) Appl. No.: 18/716,117

(22) PCT Filed: Nov. 18, 2022
(86) PCT No.: PCT/EP2022/082519

§ 371 Date: Jun. 3, 2024

Related U.S. Application Data
(60) Provisional application No. 63/361,392, filed on Dec. 15, 2021.

(51) Int. Cl. G03F 7/00

(52) U.S. Cl. CPC G03F 7/70655; G03F 7/706837; G03F 7/706841; G03F 7/706845

(57) ABSTRACT

A method for processing images for metrology using a charged particle beam tool may include obtaining, from the charged particle beam tool, an image of a portion of a sample. The method may further include processing the image using a first image processing module to generate a processed image. The method may further include determining image quality characteristics of the processed image and determining whether the image quality characteristics of the processed image satisfy predetermined imaging criteria. The method may further include in response to the image quality characteristics of the processed image not satisfying the imaging criteria, updating a tuning condition of the charged-particle beam tool, acquiring an image of the portion of the sample using the charged-particle beam tool that has the updated tuning condition, and processing the acquired image using the first image processing module to enable the processed acquired image to satisfy the predetermined imaging criteria.

### CROSS-REFERENCE TO RELATED APPLICATIONS

This application claims priority of U.S. application 63/361,392 which was filed on Dec. 15, 2021 and which is incorporated herein in its entirety by reference.

### TECHNICAL FIELD

The embodiments provided herein relate to image processing for after-development-inspection (ADI) metrology applications.

### BACKGROUND

Charged particle beam metrology systems may be used in process control for some semiconductor manufacturing processes. For example, a critical dimension scanning electron microscope (CD SEM) may be used as a dedicated system for measuring the dimensions of fine patterns formed on a semiconductor wafer. High accuracy and high precision are necessary to determine whether a particular CD SEM may be appropriate for controlling a specific process. High resolution SEM tools have been established as the standard for direct critical dimension measurements in many advanced semiconductor manufacturing processes.

However, the bombardment of energetic particles as used in an SEM tool on sensitive materials on a wafer surface, such as photoresists used in lithographic patterning, can have a negative effect on measurements. For example, bombardment of electrons on electron sensitive materials may damage the target topography and introduce measurement uncertainty.

In general, it is crucial that an SEM is in a proper condition before starting any measurements on it. In other words, it is important to check if the SEM image is metrology-ready while lowering the wafer damage risk as much as possible before subjecting it to the metrology process.

### SUMMARY

Embodiments of the present disclosure provide systems and methods for processing images for metrology using charged particle beam tools.

Some embodiments provide a method for processing images for metrology using a charged particle beam tool, the method comprising: obtaining, from the charged particle beam tool, an image of a portion of a sample; processing the image using a first image processing module to generate a processed image; determining image quality characteristics of the processed image; determining whether the image quality characteristics of the processed image satisfy predetermined imaging criteria; and in response to the image quality characteristics of the processed image not satisfying the predetermined imaging criteria: updating a tuning condition of the charged-particle beam tool; acquiring an image of the portion of the sample using the charged-particle beam tool that has the updated tuning condition; and processing the acquired image using the first image processing module to enable the processed acquired image to satisfy the predetermined imaging criteria.

Some embodiments provide a system for processing images for metrology using a charged particle beam tool comprising: a memory storing a set of instructions; and
at least one processor configured to execute the set of instructions to cause the system to perform: obtaining, from the charged particle beam tool, an image of a portion of a sample; processing the image using a first image processing module to generate a processed image;
determining image quality characteristics of the processed image; determining whether the image quality characteristics of the processed image satisfy predetermined imaging criteria; and in response to the image quality characteristics of the processed image not satisfying the predetermined imaging criteria: updating a tuning condition of the charged-particle beam tool; acquiring an image of the portion of the sample using the charged-particle beam tool that has the updated tuning condition; and processing the acquired image using the first image processing module to enable the processed acquired image to satisfy the predetermined imaging criteria.

Some embodiments provide a non-transitory computer readable medium that stores a set of instructions that is executable by at least one processor of a computing device to cause the computing device to perform a method for processing images for metrology using a charged particle beam tool, the method comprising: obtaining, from the charged particle beam tool, an image of a portion of a sample; processing the image using a first image processing module to generate a processed image; determining image quality characteristics of the processed image; determining whether the image quality characteristics of the processed image satisfy predetermined imaging criteria; and in response to the image quality characteristics of the processed image not satisfying the predetermined imaging criteria: updating a tuning condition of the charged-particle beam tool; acquiring an image of the portion of the sample using the charged-particle beam tool that has the updated tuning condition; and processing the acquired image using the first image processing module to enable the processed acquired image to satisfy the predetermined imaging criteria.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIGS. 1A-1D are diagrams illustrating a cross sectional view of a wafer, consistent with embodiments of the present disclosure.

FIGS. 2A and 2B are diagrams illustrating exemplary patterns for measurement, consistent with embodiments of the present disclosure.

FIGS. 2C and 2D are diagrams illustrating exemplary relationships of behavior of electron sensitive materials, consistent with embodiments of the present disclosure.

FIG. 3 is a schematic diagram illustrating an exemplary electron beam inspection (EBI) system, consistent with embodiments of the present disclosure.

FIGS. 4A and 4B are diagrams illustrating exemplary electron beam tools that can be part of the exemplary electron beam inspection system of FIG. 3, consistent with embodiments of the present disclosure.

FIGS. 5A-5D are diagrams illustrating various views of a wafer, consistent with embodiments of the present disclosure.

FIG. 6 is a block diagram of an exemplary system for SEM image condition tuning and processing for metrology, consistent with embodiments of the present disclosure.

FIG. 7 is a block diagram of an image processing module included in the system of FIG. 3, consistent with embodiments of the present disclosure.

FIG. 8 is a block diagram of a detailed implementation of the image processing module illustrated in FIG. 6 and FIG. 7, consistent with embodiments of the present disclosure.

FIG. 9 is an illustration of exemplary SEM images after being processed by the image processing module shown in FIG. 6 and FIG. 7, consistent with embodiments of the present disclosure.

FIG. 10 is a process flowchart representing an exemplary method for SEM image condition tuning and processing for metrology, consistent with embodiments of the present disclosure.

FIGS. 11A and 11B are exemplary tables showing image quality metric comparison and measurement metric comparison respectively.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Additionally, various embodiments directed to an inspection process disclosed herein are not intended to limit the disclosure. The embodiments disclosed herein are applicable to any technology involving defect classification, automated defect classification, or other classification or layout optimization systems and are not limited to, inspection and lithography systems.

As mentioned above, bombardment of energetic particles as used in an SEM tool on sensitive materials on a wafer surface, such as photoresists used in lithographic patterning, can have a negative effect on measurements. For example, bombardment of electrons on electron sensitive materials may damage the target topography and introduce measurement uncertainty.

In order avoid the damage to as such, particularly a low dosage of bombardment (also known as low dosage SEM condition) is particularly used in after-development-inspection (ADI) metrology. However, with low dosage, the SEM image may contain a substantial amount of noise and blurred features. These factors lead to metrology performance degradation. Existing solutions to this problem include using more SEM image frame averages during image acquisition, applying Gaussian smoothing, or mapping low quality images to high quality images. All of these solutions have various disadvantages such as a required increase in dosage, an inability to recover blurred features, and a difficulty in obtaining high quality images, respectively. Therefore, particularly in low dosage ADI metrology, there is a need for a better solution in order to increase the performance of measurements.

Embodiments of the present disclosure overcome the issues of conventional low dosage ADI metrology techniques by providing a system and process for improving the performance of ADI metrology by checking and tuning the conditions of SEM images before they are subject to the metrology process.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or

B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

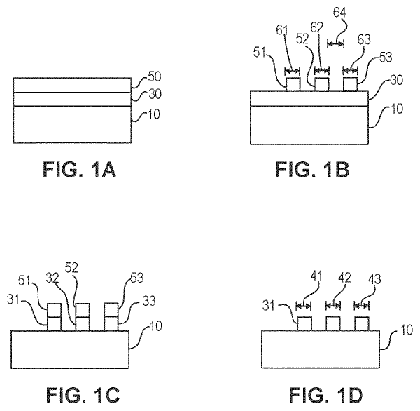

In some exemplary embodiments, electron sensitive materials are used in semiconductor processing, such as a photo resist. Metrology may comprise conducting measurements of a photo resist pattern after exposure and development, for example, in after-development-inspection (ADI). As shown in FIG. 1A, a semiconductor device 1 may comprise a substrate 10 having a thin film layer 30 formed thereon. Thin film layer 30 may be a precursor to a wiring layer. Thin film layer 30 may have a photo resist layer 50 formed thereon. After patterning and development, photo resist layer 30 may be reduced to photo resist portion 51, photo resist portion 52, and photo resist portion 53, as shown in FIG. 1B.

After developing photo resist layer 30, etching may be performed to reduce thin film layer 30 to wiring portion 31, wiring portion 32, and wiring portion 33, as shown in FIG. 1C. Metrology may also comprise conducting measurements of a wiring pattern after etching processing, for example, in after-etch-inspection (AEI).

In some embodiments, metrology may be performed by measuring photo resist portions, for example, taking a measurement 61, measurement 62, and measurement 63, as shown in FIG. 1B. Additionally, critical dimension measurement may comprise measuring a width of a pattern, such as measurement 61, or an edge-to-edge distance between patterned features, such as measurement 64, for example.

Photo resist materials may be sensitive to electron bombardment, which may affect their shape. Photo resist shrinkage is strongly correlated to landing energy and dosage of the incoming electron bombardment. In some cases, the width of a photo resist pattern may shrink by approximately 1 to 4% of its size due to electron bombardment. For example, in an exemplary pattern of 54 nm wide photo resist lines, when a 300 eV beam is used on a sample, the photo resist may experience shrinkage of 0.54 to 2.01 nm. Additionally, when a 500 eV beam is used on the sample, the photo resist may experience a shrinkage of 0.48 to 2.68 nm.

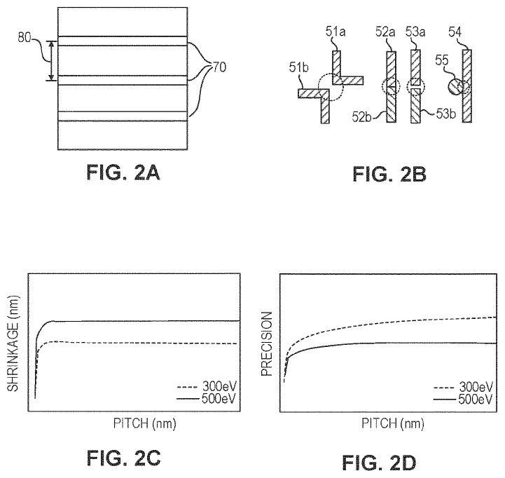

FIG. 2A illustrates an exemplary pattern of photo resist lines 70 having a standard width of 54 nm. A pitch 80 may be defined as a center-to-center separation of the repeating pattern of lines 70. Critical dimension metrology of such a sample may comprise conducting leading-edge measurements, one-dimensional length measurements of a line-space pattern, and the like. Critical dimension metrology may also be applied to features having other shapes, such as corners of traces 51a, 51b, connection between traces 52a, 52b, pitch of traces 53a, 53b, and connection between trace 54 and electrode 55, as shown in FIG. 2B, for example.

FIG. 2C illustrates a relationship of photo resist shrinkage as affected by various parameters. As shown in FIG. 2C, higher beam energy corresponds to larger shrinkage. FIG. 2C also demonstrates that photo resist shrinkage may be pattern-dependent. For example, as pitch increases, shrinkage also increases.

FIG. 2D illustrates a relationship of measurement precision as affected by various parameters. A lower numerical value of precision is desirable. As shown in FIG. 2D, using higher beam energy may result in better precision. On the other hand, using lower beam energy may result in a deterioration of precision. However, as mentioned above, using higher beam energy also results in photo resist shrinkage. Thus, metrology of electron sensitive materials involves counteracting effects.

Additionally, repeated scanning of the same area can have a negative impact on the measured pattern. For example, in some techniques, frame averaging may be used. In a frame averaging technique, multiple images of the same area are captured and measurements are averaged across the total number of frames. An exemplary comparative frame averaging method may use the following experimental conditions. Landing energy: 300 eV. Scan rate: 14 MHz. Beam current: 8 pA. Number of frames: 16. Pixel size: 0.66 nm.

A measure of dosage may be estimated as electrons per nm-sq, which may be determined by the following equation:

$$electrons per nm - sq = \frac{beam current \times dwell time \times frames}{electron charge \times pixel {size}^{2}} \qquad ( 1 )$$

Thus, in an exemplary comparative frame averaging method, a value of electrons per nm-sq may be approximately 130. A value of precision may be represented by 3×σ of measurement width (that is, three times a standard deviation of the measured width values). In some embodiments, the precision may represent measurement repeatability of a CD SEM tool.

Frame averaging may be useful for enhancing precision since multiple measurements can be taken and compared, thus increasing confidence in the feature measurement. However, repeated scanning may result in increased incident electron dosage, and may result in increased damage to the sample.

In some other embodiments, precision may refer to the closeness of a plurality of measurements to each other. Due to the nature of SEM imaging, reduced dosage of incident electrons on a sample imaging surface may result in inferior image quality and low SNR. Thus, measurements taken at a low dosage may have some degree of measurement uncertainty. Increasing the dosage may be one way to reduce measurement uncertainty because a better-quality image can be produced. Measured values based on higher dose images may seem more reliable. However, as discussed above, electron bombardment can cause the sample to change. Thus, measurements taken at higher dosages may not necessarily lead to superior precision because the values measured at earlier frames reflect the shape of the sample before damage has occurred. That is, with high dosage and multiple scanning of the same imaging area, the dimensions of the sample may change over the course of the measurement process.

In some exemplary embodiments, to minimize the impact of high energy electron bombardment, individual frame-averaging images can be used from different points on a sample surface. Based on an assumption that a pattern of interest may be repeated at different points on the sample, and that corresponding environments remain consistent at different measurement points, a technique can be applied where measurement precision is enhanced while damage to the sample is minimized.

For example, in an exemplary method, measurement conditions may be used such that a low electron dosage is applied to a sample. When electron dosage is low, precision may be limited. Thus, to recover precision, image averaging can be conducted over a plurality of images at different locations on the sample, thus increasing the number of measurements of corresponding patterns while minimizing sample damage and preserving the sample surface topology.

For example, a comparative frame averaging process may comprise scanning a location 16 times. For example, four different locations can be used. A single location may be scanned only four times and can be averaged to obtain precision similar to the comparative frame averaging process.

In some embodiments, a plurality of different locations may comprise corresponding patterns. Location data to identify the plurality of different locations may be based on user input, wafer design, image analysis, and the like. For example, a wafer can be designed to have identical regions in different locations for the purpose of conducting image averaging. Location data may be based on designs of the wafer, such as GDS (Graphic Data System) or OASIS (Open Artwork System Interchange Standard) designs. The regions may be, for example, calibration standard patterns. The regions can also be functional patterns. Alternatively, regions having corresponding geometries can be selected after a wafer has already been designed or constructed. Corresponding locations may be fabricated under the same process conditions. Imaging may be conducted under low dosage conditions at the plurality of different locations. Then, an algorithm may average measurement data collected at the plurality of different locations.

While the term identical is used to describe corresponding patterns in some exemplary embodiments, it is understood that corresponding patterns at different locations on a wafer may have some variation due to manufacturing stochastics. Thus, identical patterns may be interpreted to mean patterns having substantially the same geometry.

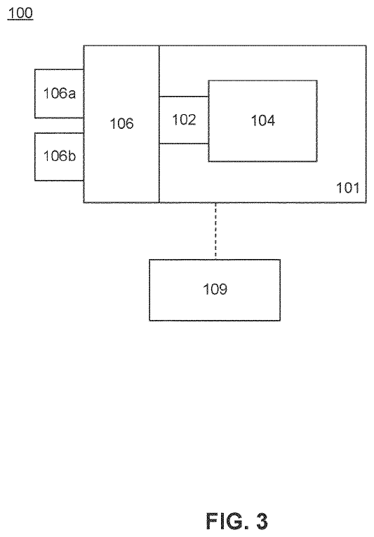

Reference is now made to FIG. 3, which illustrates an exemplary electron beam inspection (EBI) system 100 consistent with embodiments of the present disclosure. As shown in FIG. 3, EBI system 100 includes a main chamber 101 a load/lock chamber 102, an electron beam tool 104, and an equipment front end module (EFEM) 106. Electron beam tool 104 is located within main chamber 101. EFEM 106 includes a first loading port 106a and a second loading port 106b.

EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be collectively referred to as “wafers” hereafter).

One or more robot arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robot arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system. A controller 109 is electronically connected to the electron beam tool 104. The controller 109 may be a computer configured to execute various controls of the EBI system.

Conducting critical dimension metrology may comprise subjecting a wafer to inspection a plurality of times. For example, the wafer may undergo a load/unload procedure a plurality of times to collect measurement data from a plurality of runs.

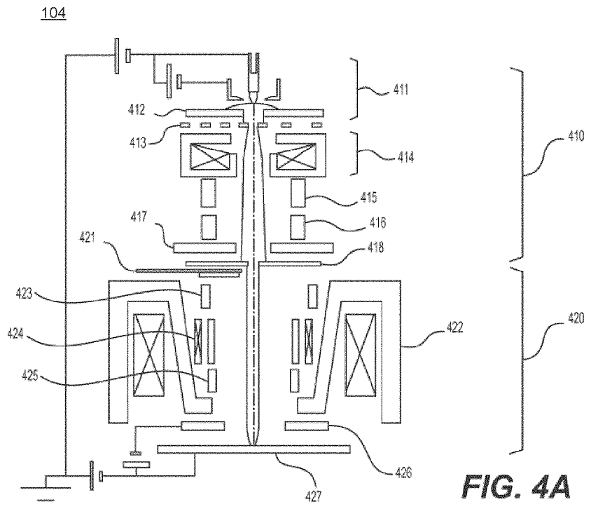

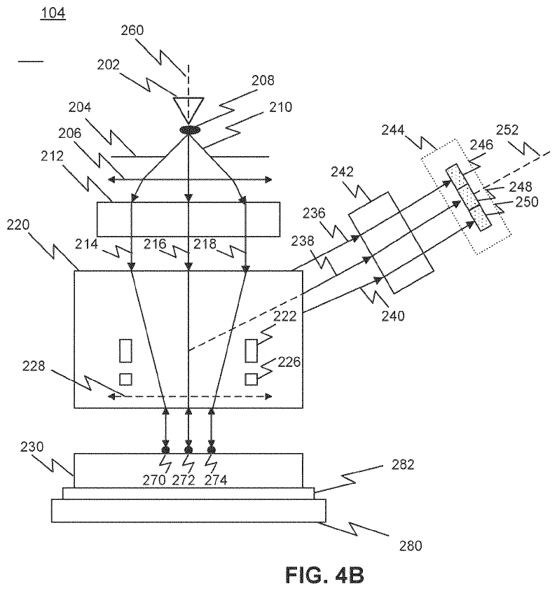

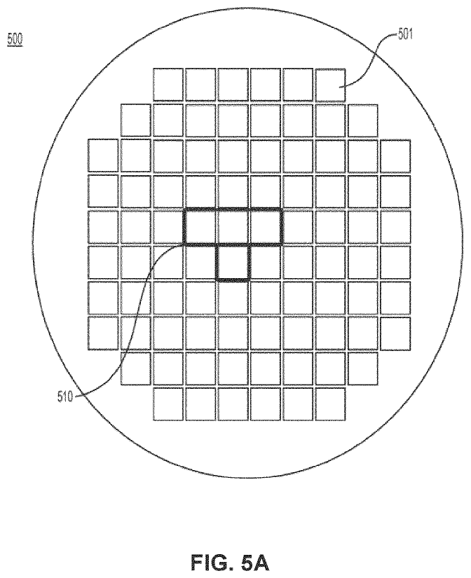

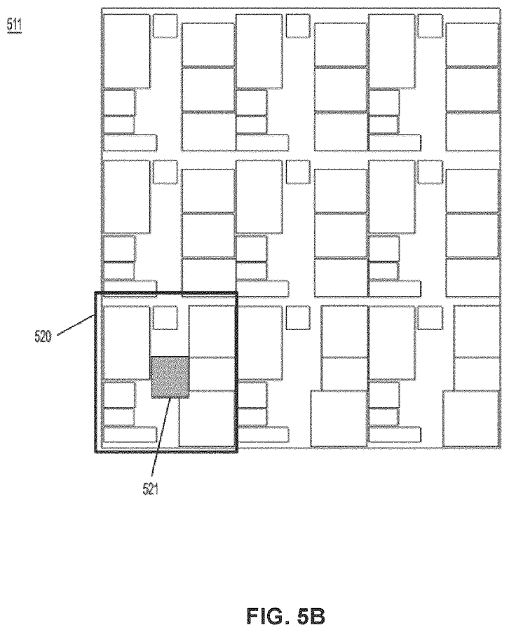

FIG. 4A illustrates an electron beam tool 104 that may be configured for use in EBI system 100. Electron beam tool 104 may be a single beam apparatus, as shown in FIG. 4A, or a multi-beam apparatus.

As shown in FIG. 4A, an electron beam tool 104 may comprise an electron gun portion 410 and an electron column portion 420. Electron gun portion 410 may comprise a cathode 411, a gun aperture 412, a movable strip aperture 413, a condenser lens 414, a beam blanker 415, an astigmatism corrector 416, a gate valve 417, and an objective aperture 418. Electron column portion 420 may comprise a first detector 421, a magnetic lens 422, a second detector 423, a Wien filter 424, a third detector 425, an objective electrode 426, and a wafer plane 427.

Reference is now made to FIG. 4B, which illustrates an electron beam tool 104 (also referred to herein as apparatus 104) that may be configured for use in a multi-beam image (MBI) system. Electron beam tool 104 comprises an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 4B), multiple secondary electron beams 236, 238, and 240, a secondary optical system 242, and an electron detection device 244. Primary projection optical system 220 can comprise a beam separator 222, deflection scanning unit 226, and objective lens 228. Electron detection device 244 can comprise detection sub-regions 246, 248, and 250.

Electron source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and electron detection device 244 can be aligned with a secondary optical axis 252 of apparatus 104.

Electron source 202 can comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 can block off peripheral electrons of primary electron beam 210 to reduce Coulomb effect. The Coulomb effect can cause an increase in size of probe spots. Source conversion unit 212 can comprise an array of image-forming elements (not shown in FIG. 4B) and an array of beam-limit apertures (not shown in FIG. 4B). The array of image-forming elements can comprise an array of micro-deflectors or micro-lenses. The array of image-forming elements can form a plurality of parallel images (virtual or real) of crossover 208 with a plurality of beamlets 214, 216, and 218 of primary electron beam 210. The array of beam-limit apertures can limit the plurality of beamlets 214, 216, and 218.

Condenser lens 206 can focus primary electron beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for inspection and can form a plurality of probe spots 270, 272, and 274 on surface of wafer 230.

Beam separator 222 can be a beam separator of Wien filter type generating an electrostatic dipole field and a magnetic dipole field. In some embodiments, if they are applied, the force exerted by electrostatic dipole field on an electron of beamlets 214, 216, and 218 can be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 can also be non-zero. Beam separator 222 can separate secondary electron beams 236, 238, and 240 from beamlets 214, 216, and 218 and direct secondary electron beams 236, 238, and 240 towards secondary optical system 242.

Deflection scanning unit 226 can deflect beamlets 214, 216, and 218 to scan probe 9 spots 270, 272, and 274 over a surface area of wafer 230. In response to incidence of beamlets 214, 216, and 218 at probe spots 270, 272, and 274, secondary electron beams 236, 238, and 240 can be emitted from wafer 230. Secondary electron beams 236, 238, and 240 can comprise electrons with a distribution of energies including secondary electrons (energies 50 eV) and backscattered electrons (energies between 50 eV and landing energies of beamlets 214, 216, and 218). Secondary optical system 242 can focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of surface area of wafer 230. Reference will now be made to an exemplary image averaging process.

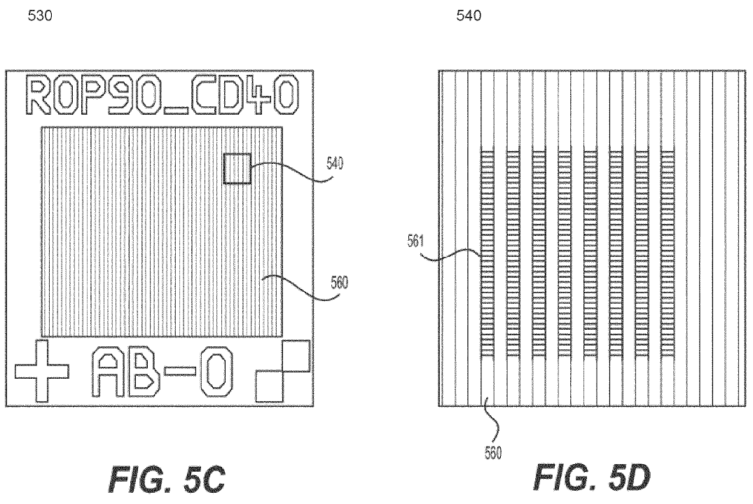

FIG. 5A depicts an exemplary wafer 500. Wafer 500 may be an electron sensitive wafer such as a negative tone development deep ultra-violet after development inspection (NTD DUV ADI) wafer. Wafer 500 comprises a plurality of dies 501. In some embodiments, a selection of four dies 510 may be taken for averaging. In one of the selected dies, there may be provided a field map 511, as shown in FIG. 5B. In field map 511, a test field 520 can be selected. Test field 520 comprises a test area 521.

Test area 521 may be a test key 530, as shown in FIG. 5C. A plurality of lines 560 may be provided in test key 530. Test key may be specified as a line-space pattern of CD40P90. That is, a standard critical dimension of line width is 40 nm and pitch of the lines is 90 nm. Test area 521 comprises an imaging area 540, as shown in FIG. 5D. In an imaging process, an image 550 may be captured under various conditions, such as a field of view (FOV) of 1 μm and a pixel size of 1 nm. In a measuring process, critical dimensions may be measured using an I-I-marker 561 superimposed on image 550. In one example, 320 I-I-markers are used in one image, and a critical dimension is calculated by averaging individual measurements.

A better understanding of the present disclosure may be obtained through the following examples, which are set forth to illustrate but are not to be construed as limiting, the embodiments of the present disclosure.

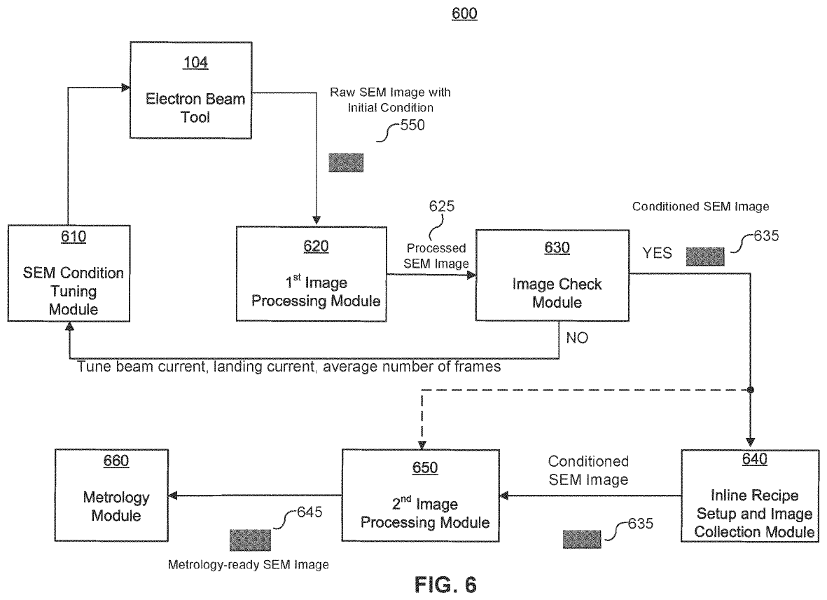

FIG. 6 depicts an exemplary system 600 for SEM condition tuning and image processing for metrology, consistent with embodiments of the present disclosure. In some embodiments, an SEM condition tuning and image processing system 600 comprises one or more processors and memories. It is appreciated that in various embodiments SEM condition tuning and image processing system 600 may be part of or may be separate from a charged-particle beam inspection system (e.g., EBI system 100 of FIG. 1). In some embodiments, SEM condition tuning and image processing system 600 may include one or more components (e.g., software modules) that can be implemented in controller 109 or system 290 as discussed herein.

The SEM image can be image 550 of the wafer 500 shown in FIGS. 5A & 5D. The image 550 may be produced by the imaging portion of the EBI system explained with respect to the previous figures for example by the electron beam tool (EBT) 104. The system 600 is configured to check the SEM image 550 and further tune the condition of the SEM so that the SEM image produced by it is suitable for metrology. The SEM condition may be indicative of several SEM image quality characteristics (herein after “characteristics”) including beam load current, landing current, number of frames per image, etc. In some embodiments, several SEM images can be captured and provided to the system 600, and for each image or a number of images, the condition can be checked. If the image characteristics meet the predetermined imaging criteria, then the SEM condition may be considered as suitable for metrology. The predetermined imaging criteria, also referred to as “threshold metrology criteria”, may be based on one or more of noise level, image resolution measure, and ellipse fitting confidence score.

As shown, the system 600 includes an SEM condition tuning module 610, a first image processing module 620, an image check module 630, an inline recipe setup and image collection module 640, a second image processing module 650, and a metrology module 660. Each of these modules can be a packaged functional hardware unit having circuitry designed for use with other components or a part of a program that performs a particular function of related functions.

The SEM condition tuning module 610 is configured to tune or adjust the SEM condition and operate in conjunction with the EBT 104, which generates the SEM image 550 described above. The image 550 may also be referred to as a “raw SEM image.” In some embodiments, there may be several raw SEM images captured from the EBT 104. The raw SEM image 550 may be associated with an SEM condition which relates to certain parameters such as a beam current, a landing current, and number of scanning frames. These parameters may translate to image characteristics such as a noise level, a resolution, and an ellipse fitting confidence. In some embodiments, the SEM condition tuning module 610 is configured to tune or adjust the SEM condition if the SEM image characteristics do not fit within the predetermined imaging criteria. The predetermined imaging criteria can be defined by a reference noise level, a reference resolution, and a reference ellipse fitting confidence score. In some embodiments, a reference noise level is a maximum noise level which a metrology module can handle without affecting the measurements. In some embodiments, a reference resolution is a minimum required resolution for metrology. In some embodiments, an ellipse fitting confidence score may represent how well the image pixels correlate to image data in the raw SEM image, and therefore, a reference ellipse fitting confidence score may be a minimum required ellipse fitting confidence score required for metrology.

In general, the ellipse fitting confidence score may indicate on a scale of 0-1 how well the predetermined imaging criteria are satisfied, with 1 being the perfect fit. The predetermined imaging criteria eventually allow for accurate measurements. For example, referring back to FIG. 5C, if the standard critical dimension of line width is 40 nm and pitch of the lines is 90 nm, then for the SEM image 550, there may be a preferred range of the reference values noise, resolution, and ellipse confidence score that are required to be satisfied in order to measure and check if the lines in the SEM image meet those critical dimensions.

As will be explained in the following paragraphs, the first image processing module 620 and the SEM readiness checked module 630 are configured to check is the raw SEM image 550 meets at least the above-mentioned predetermined imaging criteria (noise, resolution, and ellipse confidence score). If the raw SEM image 550 meets the predetermined imaging criteria, then the SEM condition (e.g., values of beam current, landing current, and number of frames) may be suitable for metrology and that particular image is considered to be in a metrology-ready condition, meaning that the values of beam current, landing current, and average number of frames are such that the corresponding raw SEM image 500 if subject to metrology will result in proper measurements. Such an image may also be referred to as a “metrology-ready” image. The standard values of beam current, landing current, and number of frames that result in a raw SEM image meeting the predetermined imaging criteria can be referred to as a reference beam current, a reference landing current, and a reference number. These values can also be collectively referred to as a reference condition. Similarly, an SEM image having a reference noise level, a reference resolution, and a reference ellipse fitting confidence score may be considered as a reference image. It may be appreciated that the reference SEM image should meet the predetermined imaging criteria.

At first, the raw SEM image 550 is provided to the first image processing module 620. It may be assumed that the raw SEM image 550 is a low-resolution image. In some embodiments, the first image processing module 620 comprises one or more self-supervised neural networks in order to process the raw SEM image 550. The first image processing module 620 is configured to be self-supervised to de-noise the image, extract pixel information, and extract image characteristics from the raw SEM image 550 and output a processed image 625. The processed image 625 may be provided further to the image check module 630. In some embodiments, the first image processing module 620 may be integrated with the image check module 630.

The image check module 630 is configured to compare the image characteristics (noise level, resolution, and ellipse fitting confidence) of the raw SEM image 550 with the reference noise level, resolution, and ellipse fitting confidence score to further provide a result as to whether the image 550 meets the predetermined imaging criteria. If so, the image check module 630 generates a conditioned image 635 as shown, which is further provided to the inline recipe setup and image collection module 640. If not, then the processed image 625 is provided back to the SEM condition tuning module 610, where the condition of the SEM is adjusted or tuned to re-acquire a new raw SEM image 550 from the electron beam tool 104. The re-acquired SEM image 550 is then again provided to the first image processing module 620. This process is repeated until the processed image fits within the predetermined imaging criteria. In order to implement the comparison, the image check module 630 may implement a hardware or software-based comparator.

Tuning the SEM condition may include adjusting one or more parameters of the beam current, the landing current, or number of frames used for data averaging. More particularly, adjusting the beam current may include increasing or decreasing the beam current, and adjusting the landing current may include increasing or decreasing the landing current. Adjusting the number of frames may include increasing or decreasing the number of frames used for data averaging. During tuning, the modules SEM condition tuning module 610, the first image processing module 620, and the image check module 630 may work together in an iterative fashion until the SEM condition is such that the processed image 625 meets the predetermined imaging criteria. The above process can be repeated for images of various portions of the wafer 500 and as many times as possible.

In some embodiments, the conditioned image 635 can be used to generate a metrology-ready image 645 or in other words which satisfies the predetermined imaging criteria. In order to do so, the conditioned image 635 is provided to the inline recipe setup and image collection module 640, which may be configured to store multiple conditioned images of various portions of the wafer 500. The module 640 may additionally be configured to setup a recipe for metrology. For example, certain parameters may be adjusted to prepare the collected conditioned images before starting the metrology process. For example, the inline recipe setup may include information related to e-beam dosage, brightness, contrast etc. Additionally, the inline recipe setup may include information related to determining an e-beam dosage, an e-beam landing energy, an average number of frames to be used for image acquisition, etc. This information can be used ensure that the setup can result in an image quality for successful metrology tasks.

From the inline recipe setup and image collection module 640, the conditioned image 635 may then be provided to the 2^{nd} self-supervised image processing module.

In some embodiments, the conditioned image 635 may be directly provided to the second image processing module 650. The second image processing module 650 may comprise one or more self-supervised neural networks and may be similar to the first SEM processing module 620. The second image processing module 650 may receive the conditioned image 635 and generate a metrology-ready image 645 from it which can be then provided to the metrology module 660. The module 660 is configured to perform metrology on the metrology-ready SEM image 645.

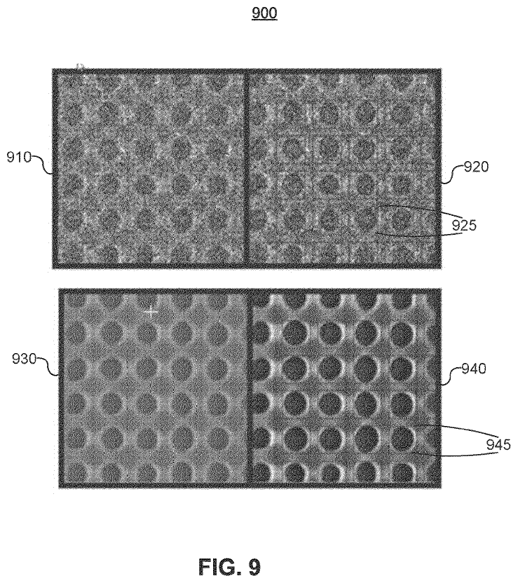

It may be appreciated that the raw SEM image 550, which does not meet the predetermined imaging criteria is a low-resolution image (shown as 910 in FIG. 9) and the metrology-ready image 645 generated is a high-resolution image (shown as image 930 in FIG. 9).

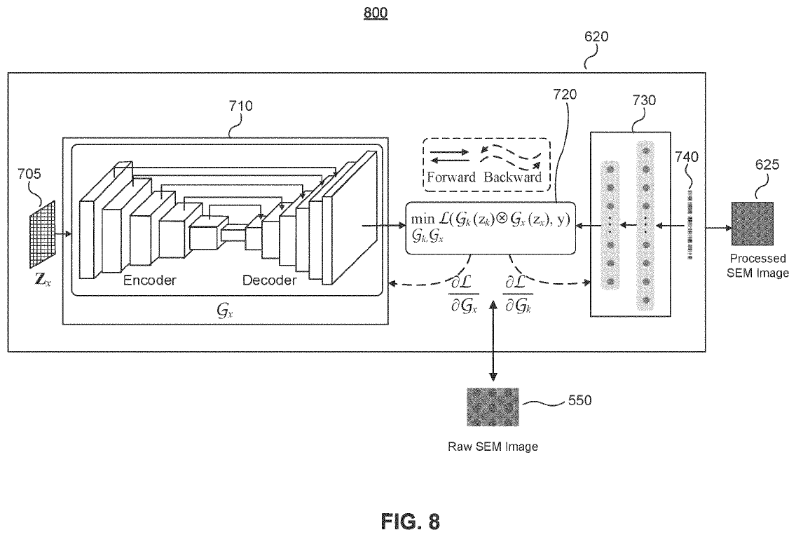

The first and the second image processing modules 620 and 650 may be configured in such a way that if a low-resolution SEM image is provided to the respective module, then it extracts the image characteristics and outputs a corresponding high-resolution image. Detailed implementations of these modules are explained later with respect to FIG. 8.

Thus, from above description it may be appreciated that the system 600 provides a two-level method of processing the SEM images for metrology. In a first level the raw SEM images are checked if those are ready for metrology by tuning the condition of the EBT 104 to generate conditioned images and in a second level the metrology-ready images are created from the conditioned images.

The system 600 can be included in the electron beam tool 104 and more particularly in the controller 109 included in the electron beam tool 104 (shown in FIGS. 4A and 4B), which in turn is included in the EBI system 100 shown in FIG. 3. Furthermore, in some embodiments, a few blocks of the system 600 may be included in the electron beam tool 104 while other blocks can be outside.

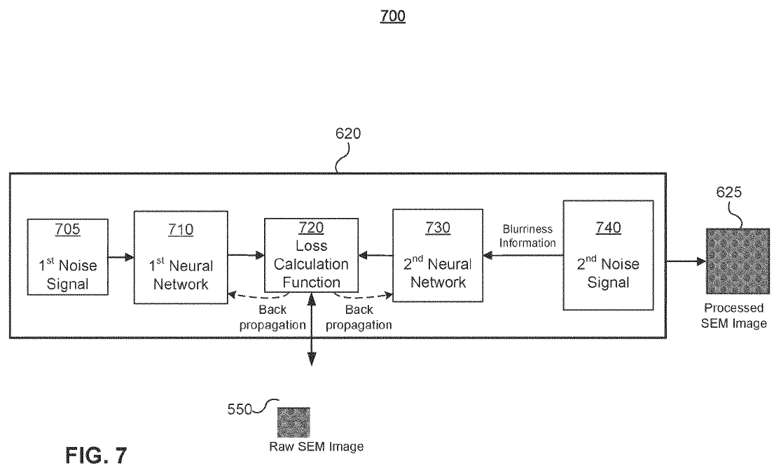

FIG. 7 is a block diagram of an example image processing module (such as the first and the second image processing modules 620 and 650, although the first image processing module 620 is shown in the figure) included in the system 600 of FIG. 6, consistent with embodiments of the present disclosure. As shown, the first image processing module 620 may include a first neural network 710, a loss function calculation 720, a second neural network 730, and a second noise signal 740. In some embodiments, first neural network 710 is configured to receive a first noise signal 705 and is self-trained to generate a sharper (de-blurred) image from the raw SEM 550. The second neural network 730 may be configured to receive the second noise signal 740. The second neural network 730 may further be configured to generate a plurality of blurring kernels (physical blurring processes), which if applied to the sharper image, can result in a blurred image, i.e., the raw SEM image 550. The sharper image generated by the first neural network 710 and the blurring kernels generated by the second neural network 730 meet in the middle to form the loss calculation function 720. The loss calculation function 720 compares the sharp (deblurred) image generated by the first neural network 710 with the raw SEM image 550 and calculates a loss, which is used to optimize both the first and the second neural networks 710 and 730 through back propagation. An example formula for the loss calculation function 720 is illustrated in FIG. 8, where £(x,y) is a mean squared error (MSE) function, Gₖ(zₖ) is the output from second neural network 730, and Gₓ(zₓ) is the output from first neural network 710).

In some embodiments, the first neural network 710 is an autoencoder type of neural network and the second neural network is fully connected neural network.

As explained earlier with regard to FIG. 6, the processed image 625 is then provided to the image check module 630 to generate a conditioned SEM image. Any common methods in the art may be used to implement the first neural network 710 and the second neural network 730.

FIG. 8 is a block diagram of a detailed implementation of the first image processing module 620 illustrated in FIG. 7, consistent with embodiments of the present disclosure. FIG. 8 shows the first neural network (Gₓ) 710 implemented using an encoder and a decoder, the second neural network (Gₖ) 730, a loss calculation function 720, a second neural network 730, and the noise signal 740. The loss function includes two variables, a first variable being [Gₓ(zₓ)⊗Gₓ(zₖ)] and a second variable being [y]. More particularly, the loss calculation function is configured to calculate the loss when a first variable Gₓ(zₖ) is combined with a second variable Gₓ(zₖ). The loss calculation function 720 is configured to work with the first neural network 710 and the second neural network 730 using a back propagation algorithm. It may be appreciated that the back propagation algorithm may optimize various parameters of the neural networks 710 and 730 such as a weight, or a bias, etc. The back propagation algorithm is an optimization algorithm and after implementing multiple iterations of the back propagation algorithm, the neural network 710 may learn to generate sharper and sharper images. Similarly, after implementing multiple iterations of the back propagation algorithm, the second neural network 730 may learn to generate more accurate blurring kernels associated with the sharper images. The raw SEM image 550 may be provided as an input at a common point of the neural network 710 and 730 and may be used to calculate the loss function. After the above process, a sharper image corresponding to the raw SEM image 550 may be generated by the image processing module 620. In other words, the raw SEM image 550 is compared against the information (the sharper images and the corresponding blurring kernels) generated by the neural networks 710 and 730. The special architecture of the neural networks 710 and 730 as such learns to generate a denoised and a deblurred version of the raw SEM image 550.

As mentioned earlier, the first neural network 710 and second neural network 730 are self-trained neural networks. In some embodiments, the first noise signal 705 is initialized at the beginning of self-training of the neural network 710 and maintained at a constant throughout the self-training process. Similarly, the second noise signal 740 is initialized at the beginning of the self-training of the second neural network 730 and maintained at a constant value throughout the self-training process. There may be many self-training iterations performed before the neural networks 710 and 730 are fully trained. As explained earlier, any common methods in the art may be used to implement various blocks in FIG. 8.

FIG. 9 is an illustration of a comparison of exemplary SEM images after being processed by conventional image processing methods and after being processed by the system 600 shown in FIG. 6, consistent with embodiments of the present disclosure. FIG. 9 includes exemplary SEM images 910, 920, 930, and 940. Image 910 is a raw SEM image without any processing. Image 920 is the SEM image 910 after being processed by a conventional image processing system. In the image 910, an ellipse fitting mesh is shown by 925, which may represent an ellipse fitting confidence score for the image 910. Image 930 is a raw SEM image without any processing. Image 940 is the SEM image 930 after being processed by the system 600 after iterative condition tuning and processing by the disclosed first and the second image processing modules 620 and 650. In the image 940, an ellipse fitting mesh is shown by 945, which may represent an ellipse fitting confidence score for the image 940. As can be seen by a simple comparison the image 940 processed by the disclosed system has a much higher resolution that the image 920 that is processed by the conventional image processing systems. Furthermore, it can be seen that the ellipse fitting mesh 945 is better fitting that the ellipse fitting mesh 925.

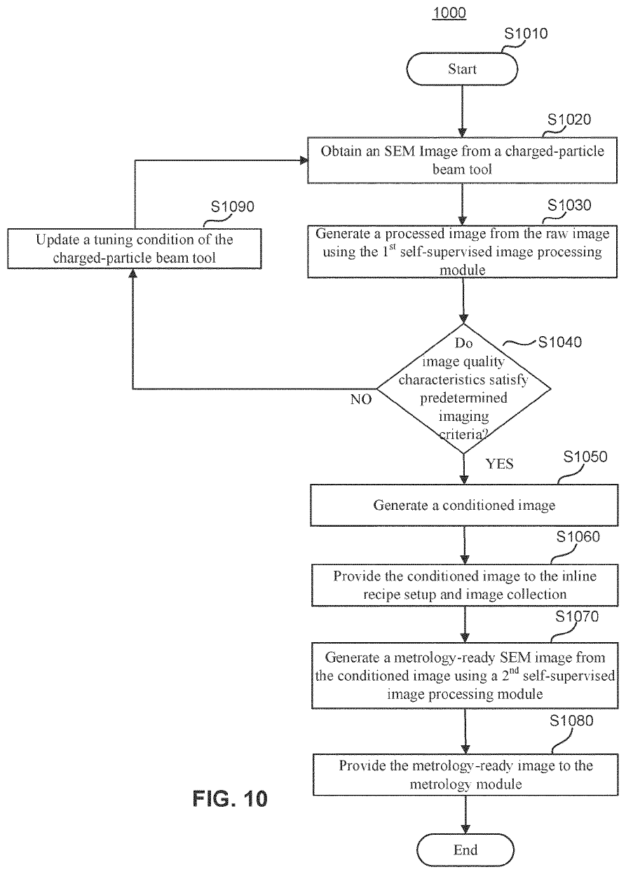

FIG. 10 is a process flowchart representing an exemplary method for SEM image condition tuning and processing for metrology, consistent with embodiments of the present disclosure. Method 1000 may be performed by a controller that may be coupled with a charged-particle beam tool (e.g., charged-particle beam inspection system 100) or an optical beam tool. For example, the controller may be controller 109 in FIG. 3. The controller may be programmed to implement method 1000.

As shown, after starting at step S1010, a raw SEM image (e.g., raw SEM image 550 of FIG. 6 or raw SEM image 910 of FIG. 9) may be acquired at step S1020 from a charged-particle beam tool, based on a pre-existing SEM tuning condition.

After acquiring the raw SEM image, the process may proceed to the step S1030. At step S1030, a processed image may be generated from the raw image using the first image processing module. For example, referring back to FIG. 6, this processing step is performed by the first image processing module 620 to generate a processed image 625.

After the image is processed, the process may proceed to step S1040. At step S1040, it may be checked whether the processed image is ready for metrology or not. For example, referring back to FIG. 6, this checking step is performed by the image check module 630.

After checking the processed image, if the processed image is ready for metrology, then the process may proceed to step S1050. At step S1050, a conditioned image may be generated. For example, referring back to FIG. 6, this step is performed by the image check module 630 if the processed image 625 is ready for metrology.

After checking the processed image, if the processed image is determined not to be ready for metrology at step S1040, then the process may proceed to the step S1090 where the tuning condition of the charged-particle beam tool may be updated. Referring back to FIG. 6, this step is performed by the image check module 630 by tuning the SEM condition using the SEM condition tuning module.

After tuning the SEM condition, the process may go back to the step S1020, where an SEM image is again acquired based on an updated tuning condition of the SEM.

After generating the conditioned image, the process may proceed to step S1060, which is an optional step. At step S1060, the conditioned image may be optionally provided to the inline recipe setup and image collection module. For example, referring back to FIG. 6, this step is performed by the image check module 630 by providing the conditioned SEM image 635 to the inline recipe setup and image collection module 640.

After generating the conditioned image 635, the process may proceed to step S1070. At step S1070, a metrology-ready SEM image may be generated from the conditioned image using a second image processing module. For example, referring back to FIG. 6. The process may then proceed to the step S1080. Referring back to FIG. 6, this step is performed by the second image processing module 650, which receives the conditioned SEM image 635 and generates the metrology-ready SEM image 645.

After generating the metrology-ready image, the process may proceed to the step S1080. At step S1080, the metrology-ready SEM image may be provided to the metrology module. For example, referring back to FIG. 6, this step is illustrated by the metrology module 660, which receives the metrology-ready image 645 to perform metrology upon.

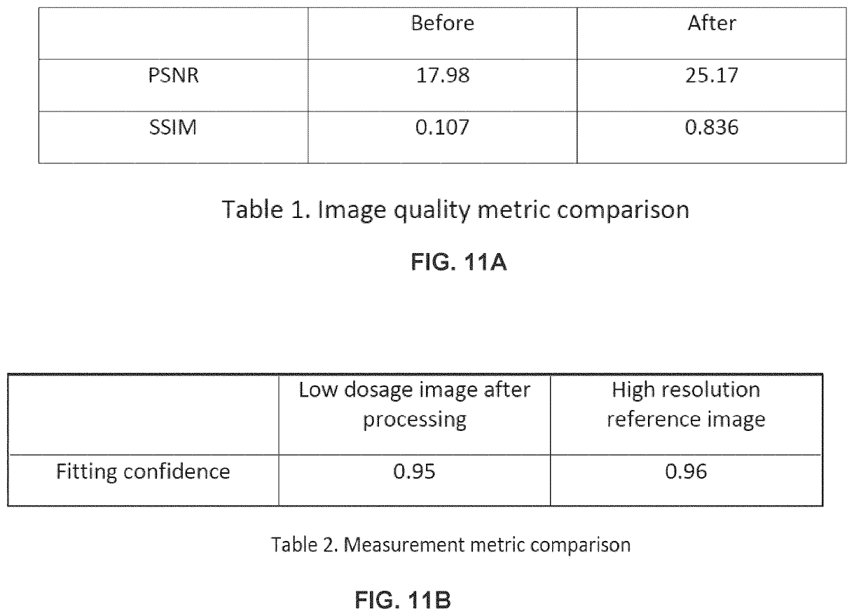

FIGS. 11A and 11B are exemplary tables showing image quality metric comparison and measurement metric comparison respectively. More particularly, FIG. 11A shows in table 1, experimental results of peak signal-to-noise ratio (PSNR) and structural similarity index metric (SSIM) on an SEM image before and after SEM condition tuning and processing by the image processing provided by system 600. The SEM image used for the experiment is a low dosage SEM image, generated by an average of approximately four frames and having a beam current of 32 pA, which is an example of a low dosage condition. In other embodiments, there may be other values of the beam current. Additionally, in order to calculate the metric, a high-resolution SEM image, generated by approximately twenty frames is used. As can be seen, before the SEM condition tuning and image processing by the system 600, the SEM image has a PSNR of 17.98 and after the SEM condition tuning and image processing by the system 600, the SEM image has a PSNR of 25.17. Similarly, before the SEM condition tuning and image processing by the system 600, the SEM image has an SSIM is 0.107 and after the SEM condition tuning and image processing by the system 600, the SEM image has an SSIM is 0.836.

FIG. 11B shows in table 2, a fitting confidence score comparison of the low dosage SEM image after SEM condition tuning and image processing by the system 600 and the high-resolution image, using an HMI ellipse fitting module having a range of [0,1] with 1 being equivalent to a perfect fit. As can be seen, the fitting confidence score of the low dosage image is 0.95 and that of the high-resolution image is 0.96. Thus, it may be appreciated that the disclosed embodiments of SEM condition tuning and image processing provide a quality improvement as well as a robust measurement key performance index (KPI) in terms of PSNR, SSIM, and an ellipse fitting confidence score.

A non-transitory computer readable medium may be provided that stores instructions for a processor (for example, processor of controller 109 of FIG. 1) to carry out image processing such as method 1000 of FIG. 10, data processing, database management, graphical display, operations of an image inspection apparatus or another imaging device, detecting a defect on a sample, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

The embodiments may further be described using the following clauses:
1. A method for processing images for metrology using a charged particle beam tool, the method comprising:
   obtaining, from the charged particle beam tool, an image of a portion of a sample;
   processing the image using a first image processing module to generate a processed image;
   determining image quality characteristics of the processed image;
   determining whether the image quality characteristics of the processed image satisfy predetermined imaging criteria; and
   in response to the image quality characteristics of the processed image not satisfying the predetermined imaging criteria:
   updating a tuning condition of the charged-particle beam tool;
   acquiring an image of the portion of the sample using the charged-particle beam tool that has the updated tuning condition; and
   processing the acquired image using the first image processing module to enable the processed acquired image to satisfy the predetermined imaging criteria.
2. The method of clause 1, further comprising:
   iteratively updating a tuning condition of the charged-particle beam tool,
   acquiring an image of the portion of the sample using the charged-particle beam tool that has the updated tuning condition, and
   processing the acquired image using the first image processing module, until the image quality characteristics of the processed image satisfy the predetermined imaging criteria.
3. The method of clause 2, further comprising:
   indicating that the processed acquired image as a conditioned image if image quality characteristics of the processed acquired image are within the predetermined imaging criteria.
4. The method of any one of the clauses 1 and 2, wherein the first image processing module comprises a first neural network and a second neural network.
5. The method of clause 3, further comprising:
   providing the conditioned image to a second image processing module to generate a metrology-ready image.
6. The method of clause 5, wherein the second image processing module comprises a third neural network and a fourth neural network.
7. The method any one of the clauses 5 and 6, further comprising performing metrology on the metrology-ready image.
8. The method of clause 1, wherein the image quality characteristics of the processed image comprises at least one of a noise level, an image resolution value, or ellipse fitting confidence value.
9. The method of any one of the clauses 1 and 8, wherein determining whether the image quality characteristics of the processed image satisfy the predetermined imaging criteria further comprises at least one of:
   comparing the noise level of the processed image to a reference noise level associated with a high-resolution image,
   comparing the resolution of the processed image to a reference resolution associated with a high-resolution image, or
   comparing the ellipse fitting confidence of the processed image to a reference ellipse fitting confidence associated with a high-resolution image.
10. The method of any one of the clauses 1, 2 and 4, wherein processing the image using the first image processing module further comprises:
   comparing the image to information generated by the first neural network and the second neural network.
11. The method of clause 10, wherein the first neural network and the second neural network are configured to receive a plurality of noise signals.
12. The method of clause 11, wherein the first neural network is configured to receive a first noise signal as a first input and to determine a first output provided to a loss calculation function for assisting with a back propagation algorithm implemented by the first neural network.
13. The method of clause 12, wherein the second neural network is configured to receive a second noise signal as a second input and to determine a second output provided to the loss calculation function for assisting with a back propagation algorithm implemented by the second neural network.
14. The method of clause 13, wherein the image is provided to the first output of the first neural network and the second output of the second neural network to interact with the loss calculation function to generate the processed image.
15. The method of clause 14, wherein the back propagation algorithm is implemented using a gradient descent method.
16. The method of any one of the clauses 4 and 10-14, wherein the first neural network and the second neural network are self-supervised and self-trained.
17. The method of clause 6, wherein the third neural network and the fourth neural network are self-supervised and self-trained.
18. The method of any one of the clauses 1 and 2, wherein updating the tuning the condition of the charged-particle beam tool further comprises at least one of:
   adjusting a beam current value of the charged particle beam tool,
   adjusting a landing current value of the charged particle beam tool, or
   adjusting a number of frames used to acquire the image.
19. A system for processing images for metrology using a charged particle beam tool comprising:
   a memory storing a set of instructions; and
   at least one processor configured to execute the set of instructions to cause the system to perform:
   obtaining, from the charged particle beam tool, an image of a portion of a sample;
   processing the image using a first image processing module to generate a processed image;
   determining image quality characteristics of the processed image;
   determining whether the image quality characteristics of the processed image satisfy predetermined imaging criteria; and
   in response to the image quality characteristics of the processed image not satisfying the predetermined imaging criteria:
   updating a tuning condition of the charged-particle beam tool;
   acquiring an image of the portion of the sample using the charged-particle beam tool that has the updated tuning condition; and
   processing the acquired image using the first image processing module to enable the processed acquired image to satisfy the predetermined imaging criteria.
20. The system of clause 19, wherein the set of instructions that are executable by the at least one processor to cause the device to further perform:
   iteratively updating a tuning condition of the charged-particle beam tool,
   acquiring an image of the portion of the sample using the charged-particle beam tool that has the updated tuning condition, and
   processing the acquired image using the first image processing module, until the image quality characteristics of the processed image satisfy the predetermined imaging criteria.
21. The system of clause 20, wherein the set of instructions that are executable by the at least one processor to cause the device to further perform:
   indicating that the processed acquired image as a conditioned image if image quality characteristics of the processed acquired image the predetermined imaging criteria.
22. The system of any one of the clauses 19 and 20, wherein the first image processing module comprises a first neural network and a second neural network.
23. The system of clause 21, wherein the set of instructions that are executable by the at least one processor to cause the device to further perform:
   providing the conditioned image to a second image processing module to generate a metrology-ready image.
24. The system of clause 22, wherein the second image processing module comprises a third neural network and a fourth neural network.
25. The system of any one of the clauses 23 and 24, wherein the set of instructions that are executable by the at least one processor to cause the device to further perform:
   performing metrology on the metrology-ready image.
26. The system of clause 19, wherein the image quality characteristics of the processed image comprises at least one of a noise level, an image resolution value, or ellipse fitting confidence value.
27. The system of any one of the clauses 19 and 26, wherein the set of instructions that are executable by the at least one processor that cause the device to determine whether the image quality characteristics of the processed image satisfy the predetermined imaging criteria, cause the device to further perform:
   comparing the noise level of the processed image to a reference noise level associated with a high-resolution image,
   comparing the resolution of the processed image to a reference resolution associated with a high-resolution image, or
   comparing the ellipse fitting confidence of the processed image to a reference ellipse fitting confidence associated with a high-resolution image.
28. The system of any one of the clauses 19, 20 and 22, wherein the set of instructions that are executable by the at least one processor that cause the device to process the image using the first image processing module further cause the device to perform:
   comparing the image to information generated by the first neural network and the second neural network.
29. The system of clause 28, wherein the first neural network and the second neural network are configured to receive a plurality of noise signals.
30. The system of clause 29, wherein the first neural network is configured to receive a first noise signal as a first input and to determine a first output provided to a loss calculation function for assisting with a back propagation algorithm implemented by the first neural network.
31. The system of clause 30, wherein the second neural network is configured to receive a second noise signal as a second input and to determine a second output provided to the loss calculation function for assisting with a back propagation algorithm implemented by the second neural network.
32. The system of clause 31, wherein the image is provided to the first output of the first neural network and the second output of the second neural network to interact with the loss calculation function to generate the processed image.
33. The system of clause 32, wherein the back propagation algorithm is implemented using a gradient descent method.
34. The method of any one of the clauses 22 and 28-32, wherein the first neural network and the second neural network are self-supervised and self-trained.
35. The method of clause 24, wherein the third neural network and the fourth neural network are self-supervised and self-trained.
36. The system of any one of the clauses 19 and 20, wherein updating the tuning the condition of the charged-particle beam tool further comprises at least one of:
   adjusting a beam current value of the charged particle beam tool,
   adjusting a landing current value of the charged particle beam tool, or
   adjusting a number of frames used to acquire the image.
37. A non-transitory computer readable medium that stores a set of instructions that is executable by at least one processor of a computing device to cause the computing device to perform a method for processing images for metrology using a charged particle beam tool, the method comprising:
   obtaining, from the charged particle beam tool, an image of a portion of a sample;
   processing the image using a first image processing module to generate a processed image;
   determining image quality characteristics of the processed image;
   determining whether the image quality characteristics of the processed image satisfy the predetermined imaging criteria; and
   in response to the image quality characteristics of the processed image not satisfying the predetermined imaging criteria:
   updating a tuning condition of the charged-particle beam tool;
   acquiring an image of the portion of the sample using the charged-particle beam tool that has the updated tuning condition; and
   processing the acquired image using the first image processing module to enable the processed acquired image to satisfy the predetermined imaging criteria.
38. The non-transitory computer-readable medium of clause 37, wherein the set of instructions that are executable by the at least one processor to cause the device to further perform:
   iteratively updating a tuning condition of the charged-particle beam tool,
   acquiring an image of the portion of the sample using the charged-particle beam tool that has the updated tuning condition, and
   processing the acquired image using the first image processing module, until the image quality characteristics of the processed image satisfy the predetermined imaging criteria.
39. The non-transitory computer-readable medium of clause 38, wherein the set of instructions that are executable by the at least one processor to cause the device to further perform:
   indicating that the processed acquired image as a conditioned image if image quality characteristics of the processed acquired image the predetermined imaging criteria.
40. The method of any one of the clauses 1 and 2, wherein the first image processing module comprises a first neural network and a second neural network.
41. The non-transitory computer-readable medium of clause 39, wherein the set of instructions that are executable by the at least one processor to cause the device to further perform:
   providing the conditioned image to a second image processing module to generate a metrology-ready image.
42. The non-transitory computer-readable medium of clause 41, wherein the second image processing module comprises a third neural network and a fourth neural network to generate the metrology-ready image.
43. The non-transitory computer-readable medium of any one of the clauses 41 and 42, wherein the set of instructions that are executable by the at least one processor to cause the device to further perform:
   comprising performing metrology on the metrology-ready image.
44. The non-transitory computer-readable medium of clause 37, wherein the image quality characteristics of the processed image comprises at least one of a noise level, an image resolution value, or ellipse fitting confidence value.
45. The non-transitory computer-readable medium of any one of the clauses 37 and 44, wherein the set of instructions that are executable by the at least one processor that cause the device to perform the determining whether the image quality characteristics of the processed image satisfy the predetermined imaging criteria, cause the device to further perform:
   comparing the noise level of the processed image to a reference noise level associated with a high-resolution image,
   comparing the resolution of the processed image to a reference resolution associated with a high-resolution image, and
   comparing the ellipse fitting confidence of the processed image to a reference ellipse fitting confidence associated with a high-resolution image.
46. The non-transitory computer-readable medium of any one of the clauses 37, 38, and 40 wherein the set of instructions that are executable by the at least one processor that cause the device to perform processing the image using the first image processing module further cause the device to perform:
   comparing the image to information generated by the first neural network and the second neural network.
47. The non-transitory computer-readable medium of clause 46, wherein the first neural network and the second neural network are configured to receive a plurality of noise signals.
48. The non-transitory computer-readable medium of clause 47, wherein the first neural network is configured to receive a first noise signal as a first input and to determine a first output provided to a loss calculation function for assisting with a back propagation algorithm implemented by the first neural network.
49. The non-transitory computer-readable medium of clause 48, wherein the second neural network is configured to receive a second noise signal as a second input and to determine a second output provided to the loss calculation function for assisting with a back propagation algorithm implemented by the second neural network.
50. The non-transitory computer-readable medium of clause 48, wherein the image is provided to the first output of the first neural network and the second output of the first neural network to interact with the loss calculation function to generate the processed image.
51. The non-transitory computer-readable medium of clause 50, wherein the back propagation algorithm is implemented using a gradient descent method.
52. The method of any one of the clauses 40 and 46-50, wherein the first neural network and the second neural network are self-supervised and self-trained.
53. The method of clause 42, wherein the third neural network and the fourth neural network are self-supervised and self-trained.
54. The non-transitory computer-readable medium of any one of the clauses 37 and 38, wherein updating the tuning the condition of the charged-particle beam tool further comprises at least one of:
   adjusting a beam current value of the charged particle beam tool,
   adjusting a landing current value of the charged particle beam tool, or
   adjusting a number of frames used to acquire the image.

It will be appreciated that the embodiments of the present disclosure are not limited to the exact construction that has been described above and illustrated in the accompanying drawings, and that various modifications and changes may be made without departing from the scope thereof.

1. A system for processing images for metrology using a charged-particle beam tool comprising:
a memory storing a set of instructions; and
at least one processor configured to execute the set of instructions to cause the system to perform:
obtaining, from the charged-particle beam tool, an image of a portion of a sample;
processing the image using a first image processing module to generate a processed image;
determining image quality characteristics of the processed image;
determining whether the image quality characteristics of the processed image satisfy predetermined imaging criteria; and
in response to the image quality characteristics of the processed image not satisfying the predetermined imaging criteria:
updating a tuning condition of the charged-particle beam tool;
acquiring an image of the portion of the sample using the charged-particle beam tool that has the updated tuning condition; and
processing the acquired image using the first image processing module to enable the processed acquired image to satisfy the predetermined imaging criteria.

2. The system of claim 1, wherein the set of instructions that are executable by the at least one processor to cause the system to further perform:
iteratively updating a tuning condition of the charged-particle beam tool,
acquiring an image of the portion of the sample using the charged-particle beam tool that has the updated tuning condition, and
processing the acquired image using the first image processing module, until the image quality characteristics of the processed image satisfy the predetermined imaging criteria.

3. The system of claim 2, wherein the set of instructions that are executable by the at least one processor to cause the system to further perform:
indicating that the processed acquired image as a conditioned image if image quality characteristics of the processed acquired image the predetermined imaging criteria.

4. The system of claim 1, wherein the first image processing module comprises a first neural network and a second neural network.

5. The system of claim 3, wherein the set of instructions that are executable by the at least one processor to cause the system to further perform:
providing the conditioned image to a second image processing module to generate a metrology-ready image.

6. The system of claim 5, wherein the second image processing module comprises a third neural network and a fourth neural network.

7. The system of claim 5, wherein the set of instructions that are executable by the at least one processor to cause the system to further perform:
performing metrology on the metrology-ready image.

8. The system of claim 1, wherein the image quality characteristics of the processed image comprises at least one of a noise level, an image resolution value, or ellipse fitting confidence value.

9. The system of claim 8, wherein the set of instructions that are executable by the at least one processor that cause the system to determine whether the image quality characteristics of the processed image satisfy the predetermined imaging criteria, cause the system to further perform:
comparing the noise level of the processed image to a reference noise level associated with a high-resolution image,
comparing the resolution of the processed image to a reference resolution associated with a high-resolution image, or
comparing the ellipse fitting confidence of the processed image to a reference ellipse fitting confidence associated with a high-resolution image.

10. The system of claim 4, wherein the set of instructions that are executable by the at least one processor that cause the system to process the image using the first image processing module further cause the system to perform:
comparing the image to information generated by the first neural network and the second neural network.

11. The system of claim 10, wherein the first neural network and the second neural network are configured to receive a plurality of noise signals.

12. The system of claim 11, wherein the first neural network is configured to receive a first noise signal as a first input and to determine a first output provided to a loss calculation function for assisting with a back propagation algorithm implemented by the first neural network.

13. The system of claim 12, wherein the second neural network is configured to receive a second noise signal as a second input and to determine a second output provided to the loss calculation function for assisting with a back propagation algorithm implemented by the second neural network.

14. The system of claim 13, wherein the image is provided to the first output of the first neural network and the second output of the second neural network to interact with the loss calculation function to generate the processed image.

15. The system of claim 1, wherein updating the tuning the condition of the charged-particle beam tool further comprises at least one of:
adjusting a beam current value of the charged-particle beam tool,
adjusting a landing current value of the charged-particle beam tool, or
adjusting a number of frames used to acquire the image.

16. A non-transitory computer-readable medium that stores a set of instructions that is executable by at least one processor of a computing device to cause the computing device to perform a method for processing images for metrology using a charged-particle beam tool, the method comprising:
obtaining, from the charged-particle beam tool, an image of a portion of a sample;
processing the image using a first image processing module to generate a processed image;
determining image quality characteristics of the processed image;
determining whether the image quality characteristics of the processed image satisfy predetermined imaging criteria; and
in response to the image quality characteristics of the processed image not satisfying the predetermined imaging criteria:
updating a tuning condition of;
acquiring an image of the portion of the sample using the charged-particle beam tool that has the updated tuning condition; and
processing the acquired image using the first image processing module to enable the processed acquired image to satisfy the predetermined imaging criteria.

17. The non-transitory computer-readable medium of claim 16, wherein the set of instructions that are executable by the at least one processor to cause the device to further perform:
iteratively updating a tuning condition of the charged-particle beam tool;
acquiring an image of the portion of the sample using the charged-particle beam tool that has the updated tuning condition; and
processing the acquired image using the first image processing module, until the image quality characteristics of the processed image satisfy the predetermined imaging criteria.

18. The non-transitory computer-readable medium of claim 17, wherein the set of instructions that are executable by the at least one processor to cause the device to further perform:
indicating that the processed acquired image as a conditioned image if image quality characteristics of the processed acquired image the predetermined imaging criteria.

19. The non-transitory computer-readable medium of claim 16, wherein the first image processing module comprises a first neural network and a second neural network.

20. The non-transitory computer-readable medium of claim 18, wherein the set of instructions that are executable by the at least one processor to cause the device to further perform:
providing the conditioned image to a second image processing module to generate a metrology-ready image.
